(19) United States
(12) Patent Application Publication
(10) Pub. No.: US 2009/0218651 A1
(43) Pub. Date: Sep. 3, 2009

(54) COMPOSITE SUBSTRATES FOR THIN FILM ELECTRO-OPTICAL DEVICES

(75) Inventors: Sergey Frolov, Murray Hill, NJ (US); Michael Cyrus, Summit, NJ (US)

Correspondence Address: MAYER & WILLIAMS PC, 251 NORTH AVENUE WEST, 2ND FLOOR, WESTFIELD, NJ, 07090, US

(73) Assignee: Sunlight Photonics Inc., South Plainfield, NJ (US)

(21) Appl. No.: 12/038,871

(22) Filed: Feb. 28, 2008

(51) Int. Cl. H01L 31/0224; B32B 3/30; B32B 3/10

(52) U.S. Cl. 257/459; 428/156; 428/131; 257/E33.001

(57) ABSTRACT

An electro-optic device includes at least one electro-optic module having first and second conductive layers and at least first and second semiconductor layers disposed between the conductive layers. At least one optically transparent, electrically insulating base substrate is disposed on the module. The base substrate has a plurality of grooves disposed therein and an electrically conducting material filling the grooves. Electrical contact is established between the conducting material and at least one of the conducting layers of the module.

### STATEMENT OF RELATED APPLICATIONS

This application is related to U.S. patent application Ser. No. ______ (Attorney Docket No. 2800/5), filed on even date herewith, entitled “Method and Apparatus for Fabricating Composite Substrates For Thin Film Electro-Optical Devices”, which is incorporated by reference in its entirety herein.

### FIELD OF THE INVENTION

The present invention relates generally to thin film electro-optic devices and methods of producing such devices. More particularly, the present invention relates to photovoltaic devices that have transparent conducting layers.

### BACKGROUND OF THE INVENTION

A variety of electro-optic devices, including flat screen displays and photovoltaic devices, are currently produced in a large area thin film form. Such devices typically require thin layers of transparent conducting material. Significant improvements in the performance of these devices may be achieved by improving the optical and electrical characteristics of such transparent conducting layers. Furthermore, these devices are usually deposited on large area substrates. There is a continuing need to improve the performance of electro-optic devices by providing substrates having electrical and optical characteristics that are superior to those of currently available transparent conducting layers.

### SUMMARY OF THE INVENTION

In accordance with the present invention, a composite substrate is provided. The composite substrate includes an optically transparent and electrically insulating base substrate, a plurality of grooves disposed in the base substrate and an electrically conducting material filling the grooves.

In accordance with one aspect of the invention, the plurality of grooves defines a pattern of grooves and the conducting material in each of the grooves collectively defines an optically nonblocking conducting grid.

In accordance with one aspect of the invention, each of the grooves has a cross-section shape that extends in a direction perpendicular to a surface of the base substrate.

In accordance with one aspect of the invention, at least one of the grooves has a triangular cross-section.

In accordance with one aspect of the invention, at least one of the grooves has a cross-section with at least one re-entrant angle.

In accordance with one aspect of the invention, the electrically conducting material is exposed at a surface of the base substrate so that it is accessible from the surface to thereby serve as electrical contacts.

In accordance with one aspect of the invention, the electrically conducting material protrudes above the surface of said base substrate.

In accordance with one aspect of the invention, a layer of transparent adhesive layer is disposed on at least one side of the base substrate.

In accordance with one aspect of the invention, a plurality of holes extends between the top and bottom surfaces of the base substrate.

In accordance with one aspect of the invention, the plurality of grooves defines a rectangular pattern of grooves.

In accordance with one aspect of the invention, the electrically conducting material is a metal material.

In accordance with one aspect of the invention, the electrically conducting material is a conducting ink.

In accordance with one aspect of the invention, the electrically conducting material is a conducting polymer.

In accordance with one aspect of the invention, a transparent conducting layer is disposed on top of the electrically conducting material to establish electrical contact therewith.

In accordance with one aspect of the invention, the base substrate is made from glass.

In accordance with one aspect of the invention, the base substrate is made from plastic.

In accordance with one aspect of the invention, the plurality of grooves includes a first plurality of grooves disposed in a first surface of the base substrate and a second plurality of grooves disposed in a second surface of the base substrate.

In accordance with one aspect of the invention, an electro-optic device includes at least one electro-optic module that includes first and second conductive layers and at least first and second semiconductor layers disposed between the conductive layers. At least one optically transparent, electrically insulating base substrate is disposed on the module. The base substrate has a plurality of grooves disposed therein and an electrically conducting material filling the grooves. Electrical contact is established between the conducting material and at least one of the conducting layers of the module.

### BRIEF DESCRIPTION OF THE DRAWINGS

FIG. 1 is a perspective view of a transparent, electrically insulating substrate having a pattern of grooves filled with an electrically conducting grid.

FIGS. 2a and 2b are cross-sectional and top views, respectively, of the transparent substrate depicted in FIG. 1.

FIGS. 3a and 3b are cross-sectional and top views, respectively, of an alternative embodiment of the transparent substrate in which the grooves in which the grid is embedded have a triangular cross-sectional shape.

FIGS. 4a-4e show various examples of alternative cross-sectional shapes for the grooves formed in the transparent substrate.

FIGS. 5A-5D show a top or plan view of various examples of alternative patterns in which the embedded conducting grid may be arranged, including straight line (FIG. 5A), triangular (FIG. 5B), hexagonal (FIG. 5C), and sinusoidal (FIG. 5D) patterns.

FIGS. 6a-6e show examples of alternative cross-sectional shapes for the grooves formed in the transparent substrate that all employ re-entrant angles.

FIG. 7 is a cross-sectional view of a single p-n junction photovoltaic device that is attached to a transparent substrate having an embedded conducting grid.

FIG. 8 shows a magnified cross-sectional view of the single p-n junction photovoltaic device and the substrate depicted in FIG. 7.

FIG. 9 is a cross-sectional view of a multi-junction photovoltaic device in which individual photovoltaic modules that each include a single junction are attached to a different transparent substrate each having an embedded conducting grid located on a single side of the substrate.

FIG. 10 is a cross-sectional view of a multi-junction photovoltaic device in which individual photovoltaic modules that each include a single junction are attached to a different transparent substrate each having an embedded conducting grid on both sides of the substrate.

FIGS. 11a and 11b show a cross-sectional and top view, respectively, of one example of a transparent substrate having an embedded conducting grid with a triangular cross-section on its upper side and an embedded conducting grid having a rectangular cross-section on its bottom side.

FIG. 12 shows a cross-sectional view of a transparent substrate having an embedded metal grid with conducting elements having a triangular cross-sectional shape and a transparent conducting layer covering its upper surface.

FIG. 13 depicts a process in which a transparent substrate having an embedded conducting grid with conducting elements having a triangular cross-sectional shape is attached to the upper conductive layer of a single junction photovoltaic device.

FIGS. 14a-14c show in cross-section alternative examples of the conducting grid in which a portion of each individual conducting element protrudes above the substrate surface.

FIGS. 15a-15c show in cross-section alternative examples of the conducting grid in which a portion of each individual conducting element protrudes above the substrate surface and in which a thin layer of a transparent adhesive is applied between the individual conducting elements.

FIGS. 16a-16d show in cross-section examples of a perforated transparent substrate with an embedded conducting grid that is formed from circular wire conducting elements, (FIG. 16a), circular wire conducting elements and an adhesive layer (FIG. 16b), square wire conducting elements with an adhesive layer (FIG. 16c), and arrow-type wire conducting elements with an adhesive layer (FIG. 16d).

FIG. 17 shows one example of an apparatus for attaching a transparent substrate having an embedded conducting grid with conducting elements that have a triangular cross-section shape to the upper conductive surface of a single junction photovoltaic device.

FIG. 18 is an example of an apparatus for attaching a transparent substrate having an embedded conducting grid with conducting elements that have an arrow-type cross-section and an adhesive layer to the upper conductive surface of a single junction photovoltaic device.

FIG. 19 shows in cross-section a transparent substrate having an adhesive layer and grooves having the cross-sectional shape of an arrow, which grooves are filled with conductive ink.

FIG. 20a is a perspective view and FIG. 20b is a top view of a transparent substrate having grooves filled with a first set of cylindrical wires extending in one direction and a second set of cylindrical wires extending in another direction which are situated above the first set of wires.

FIG. 21 is a plot of electrical and optical losses arising in various types of TCO films because of sheet resistance and optical absorbance.

FIGS. 22a and 22b are cross-sectional views of two embodiments of a transparent substrate in which the conducting grids are fully embedded.

FIG. 23 is a schematic diagram of an apparatus for attaching a composite substrate onto an electro-optic device.

### DETAILED DESCRIPTION OF THE INVENTION

### Overview

In the following detailed description, numerous specific details are set forth in order to provide a thorough understanding of exemplary embodiments or other examples described herein. However, it will be understood that these embodiments and examples may be practiced without the specific details. In other instances, well-known methods, procedures, components and circuits have not been described in detail, so as not to obscure the following description. Further, the embodiments disclosed are for exemplary purposes only and other embodiments may be employed in lieu of, or in combination with, the embodiments disclosed.

Embodiments of this apparatus and method may facilitate the ability to efficiently and economically convert electro-magnetic energy in the form of light into electrical energy in the form of electrical current. Embodiments of this apparatus and method may also facilitate large volume production and widespread usage of photovoltaic devices.

Various large area electro-optic devices currently utilize thin-layers of optically transparent and electrically conductive materials. Most prominent examples of such electro-optic devices include photovoltaic devices and light emitting devices; both of these devices make use of so-called transparent conductive oxides (TCO) materials. A number of different TCO materials have been developed in recent years, including tin oxide, indium tin oxide (ITO), zinc oxide and others. All of these materials suffer from the same drawback: in order to increase their conductivity, material thickness or doping concentration has to be increased, which in turn lowers optical transmission trough this material due to excess absorption. The present invention provides a new approach circumventing this issue and avoiding the trade off between high electrical conductivity and high optical transmission.

As detailed below, the present invention provides a transparent substrate with an embedded electrically conductive material, which simultaneously achieves high electrical conductivity and high optical transmission. It also provides methods for how this composite substrate may be used in manufacturing of electro-optic devices, including photovoltaic and light emitting devices. The present invention further provides methods and processes of manufacturing such a substrate, as well as manufacturing of electro-optic devices using this substrate.

Electrically conducting materials may be embedded into a transparent substrate in the form of a grid and exposed on at least one side to provide electrical contacts. Large area electro-optic devices, such as photovoltaic devices, may be directly deposited on and attached to such a substrate, establishing an electrical contact between a conducting layer of the device and the conducting grid of the substrate. As a result, the contact resistance that may be achieved can be substantially lower than that currently achieved when a thin metal grid is directly deposited on top of the electro-optic device's conducting layer. The conducting grid may be shaped so that the amount of light it blocks is minimal, in some cases blocking no more light than when the aforementioned conventional direct metal grid deposition technique is employed. Furthermore, in some embodiments the cross-sectional shape of the conducting grid may be arranged so that it blocks none of the transmitted light.

### EXAMPLES

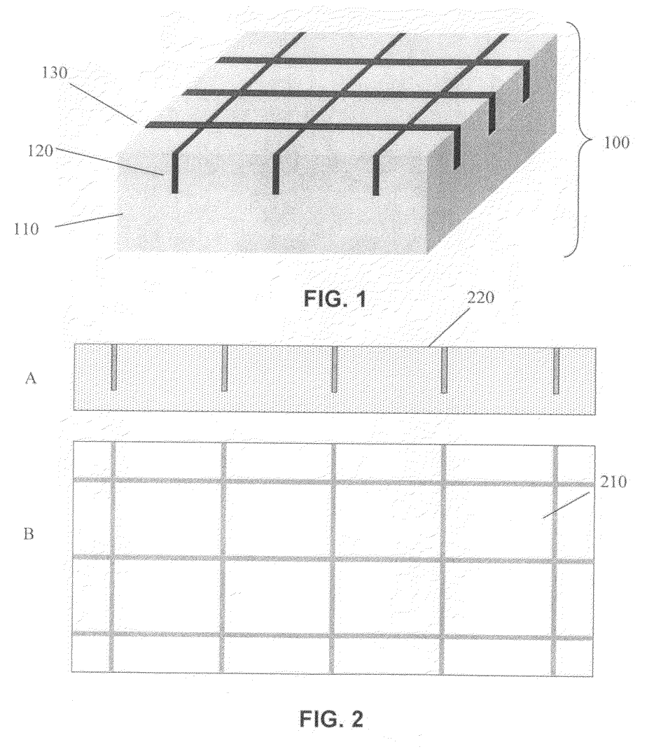

FIG. 1 shows a perspective view of one embodiment of a composite substrate 100 of the present invention, in which a transparent, electrically insulating substrate 110 has a pattern of grooves 120 that are filled with a low electrical resistance material 130. Any of a variety of different conducting materials may be used in this example: conducting epoxies, silver inks, conducting polymers, metals, including Cu, Au, Al, and others. The cross-sectional shape of the resulting conducting grid may closely match that of the grooves. The substrate material may be, for example, glass, such as soda-lime glass, polymer, such as polyimide, other crystalline or amorphous transparent insulator materials or a composite material.

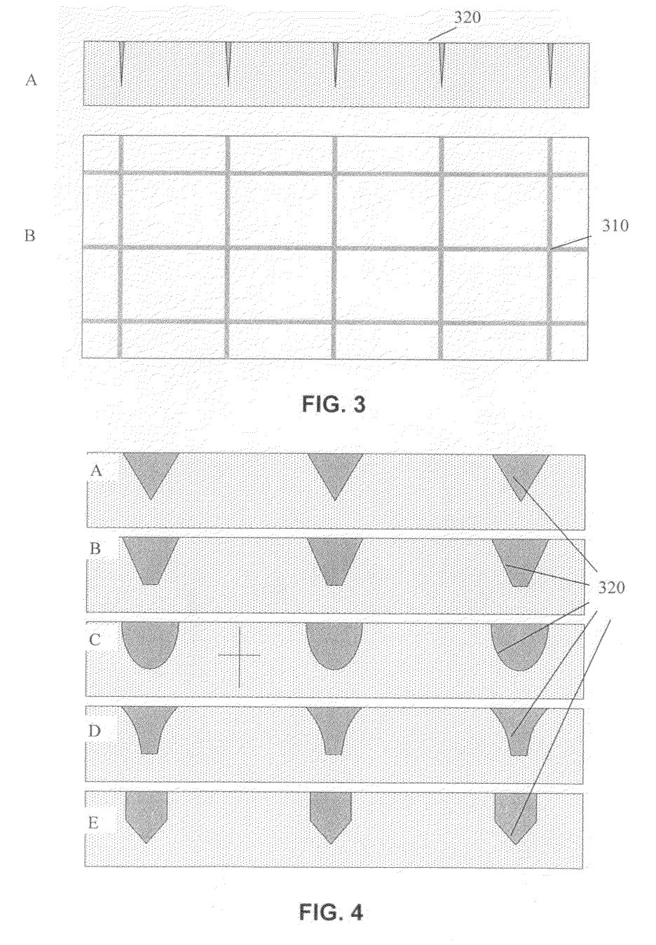

FIG. 2a is cross-sectional view of the composite substrate 100 of FIG. 1 and FIG. 2b is a top or plan view of the composite substrate 100. In this embodiment the grooves 220 have a rectangular cross-sectional shape. More generally, however, the cross-sectional shape of the grooves 220 may have any arbitrary shape, but preferably have an elongated shape with a longer dimension perpendicular to the top surface of the substrate 110. For example, FIGS. 3a and 3b show a cross-section and top view, respectively, of an embedded conducting grid 310 formed in grooves 320 that have a triangular cross-sectional shape. Examples of grooves 320 with different cross-sectional shapes are given in FIG. 4, including triangular (A), trapezoidal (B), rounded or convex (C), and concave (D).

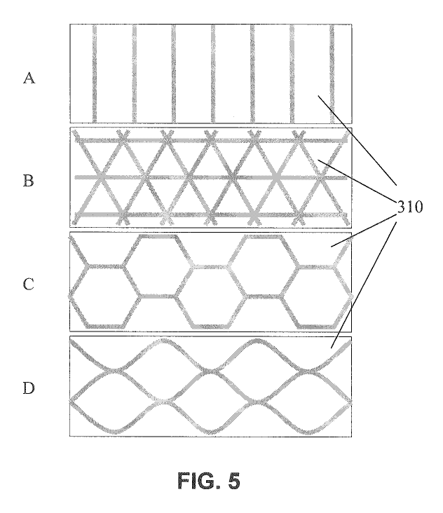

In the embodiments shown in FIGS. 1-3, the conducting grids 310 have rectangular patterns, as seen in the top view of FIGS. 2b and 3b. However, other patterns may be used as well. For instance, as shown in the top view of FIGS. 5A-5D, the grids 310 may be arranged in straight lines (A), triangular lattices (B), hexagonal lattices (C) and sinusoidal patterns (D). Of course, other conducting grid arrangements, including arrangements not shown herein, may be used as well.

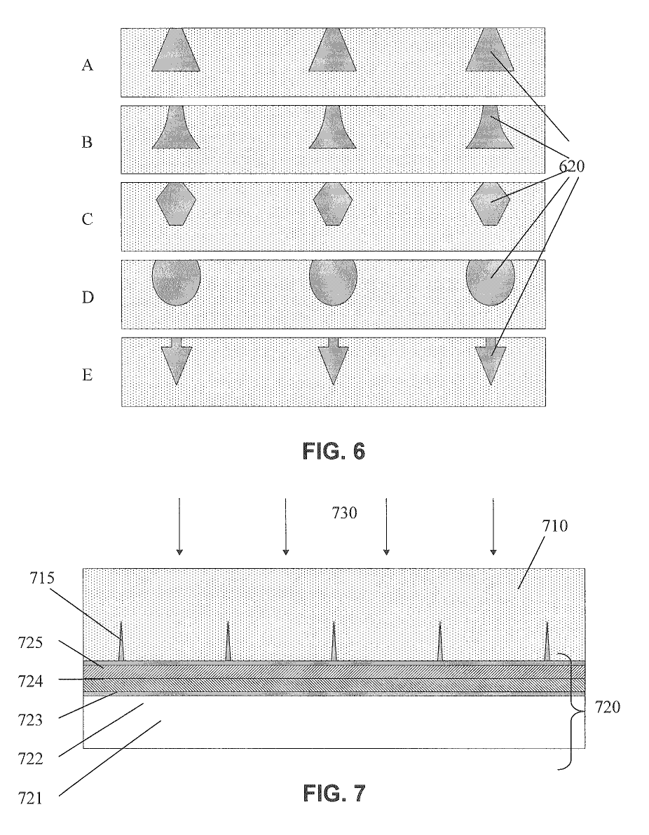

In another embodiment, the grooves in the transparent substrate may have cross-sectional shapes with re-entrant angles, i.e. shapes in which the groove's width below the substrate surface in some places may exceed the groove's width at the substrate surface. Examples of such grooves 620 are shown in FIGS. 6A-6E. A primary advantage of such grooves is that the conducting grid is held in place more firmly and may not even require adhesion between the inner surfaces of the grooves 620 and the conducting materials.

In another embodiment, shown in cross-section in FIG. 7, a transparent substrate 710 with an embedded conducting grid having triangular grooves 715 is disposed on and attached to a photovoltaic device 720, which includes at least two conducting layers 722 and 725, and two semiconductor layers 723 and 724 forming a junction at their interface. Typically, such a junction is a p-n j unction. There may be also a second substrate 721. In this embodiment light 730 is efficiently transmitted through substrate 710 and absorbed by the photovoltaic device 720, so that its energy can be converted into electrical current. The substrate 710 also makes electrical contact with the conducting layer 725, thereby significantly reducing in-series contact resistance of the photovoltaic device 720. One example of a photovoltaic or other electro-optic device that may be employed is formed from two or more photovoltaic or electro-optic modules and is disclosed in U.S. application Ser. No. 12/034,883 entitled “Multi-Layered Electro-Optic Devices,” which is hereby incorporated by reference in its entirety.

Currently available large area transparent conducting materials have a resistivity in the range of 0.2·10⁻³ to 1·10⁻³ Ωcm, which for films with a thickness in the range from 0.5 to 2 microns results in a sheet resistance of about 5 to 20 Ω/square. This range of sheet resistances is often considered an optimum range, as shown in FIG. 21. Indeed, FIG. 21 shows that lowering the resistance of a transparent conducting oxide (TCO), e.g. by increasing its thickness, will result in increased optical losses due to absorption. On the other hand, further lowering of optical losses in a TCO is hindered by an accompanying increase in its electrical resistance.

The present invention allows one to resolve this conflict between the optical and electrical losses of a TCO film. This is achieved by embedding a conducting grid in the transparent substrate, which conducting grid may be composed of a highly conducting metal, polymer or composite material. For example, gold, copper, silver and aluminum have resistivities in the range of 1.6-2.8·10⁻⁶ Ωcm, which is two orders of magnitude lower than that of any currently available TCO material. The equivalent sheet resistance of the conducting grid also depends on its cross-sectional area, which can be varied without directly affecting the optical losses due to shading (without any additional optical absorption due to the grid). For example, a rectangular copper wire grid embedded into a 20 μm by 50 μm groove and laid out on a square pattern with a 1 cm pitch will produce a sheet resistance of only 0.2 Ω/square, i.e. two orders of magnitude lower than that of a TCO film. Current approaches utilizing metal grids deposited directly on top of a TCO layers are too thin to achieve the same low resistance and also lead to excessive optical losses due to shading.

As previously mentioned, the conducting grid may be formed in grooves having a wide variety of different cross-sectional shapes, including a rectangular shape such as shown in FIG. 2a and the other elongated shapes shown in FIGS. 4 and 6. An elongated shape will often be preferred because it minimizes the shading effect of the opaque conducting grid on the performance of the photovoltaic device that is disposed on the substrate. For example, for the same cross-sectional area of the conducting grid, a 20 μm wide metal grid will obscure and shade half of the area of the underlying photovoltaic device in comparison to a 40 μm wide metal grid.

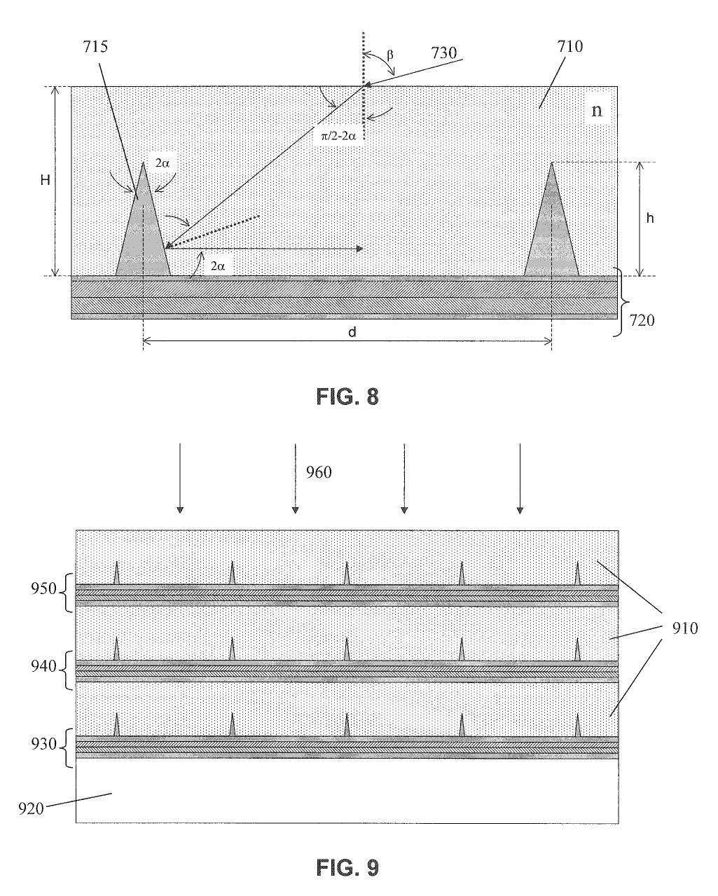

For the reasons explained below one particularly advantageous cross-section shape for the grooves formed in the substrate is a triangular shape. FIG. 8 shows a detailed cross-sectional view of the embodiment shown in FIG. 7 in which a photovoltaic module 720 is integrated with a substrate 710, where H is the substrate thickness, n is the substrates refractive index, h is the groove's height, d is the conducting grid pitch and 2α is the angle at the apex of the triangular groove. Light 730 may come to the top surface of the substrate at any angle; however, only few light rays will intercept a groove 715 along their path. Furthermore, most of these rays will be reflected, so that they still pass through the underlying photovoltaic device. However, for incidence angles larger than a certain critical angle β the light rays may be deflected away from the photovoltaic module as shown in FIG. 8. Assuming d>>h, the value of this critical angle is given by

β=asin {n cos(2α)}. (1)

Thus, it can be shown that for any given index n, there may be a range of angles α, for which none of the rays satisfy Eq. (1) and therefore all of the light is transmitted through the substrate and absorbed by the underlying photovoltaic device:

2α<acos(1/n). (2)

For example, for n=2 one may find that α has to be less than 30° in order to have all of the light rays transmitted through the substrate. Conducting grids having such triangular grooves or other shaped grooves that transmit all the light through the substrate will be referred to herein as optically unobstructing or nonblocking conducting grids.

Based on the above analysis it follows that elongated triangular conducting grids embedded in a transparent substrate may be in many cases most suitable for simultaneous lowering electrical and optical losses (due to in-series resistance and optical transmission loss, respectively) in an integrated photovoltaic device, such as the device shown in FIG. 7. Indeed, it is theoretically possible to lower electrical resistance of a nonblocking conducting grid indefinitely without any penalizing decrease in optical transmission. Nonblocking and nearly nonblocking grids may be realized using grooves having a wide variety of cross-sectional shapes other than triangular cross-sectional shapes, e.g. the shapes shown in FIG. 4 and FIGS. 6 C, 6D, and 6E.

In another embodiment of the invention shown in FIG. 9, a multi-layered photovoltaic device is composed of three photovoltaic modules 930, 940 and 950, each module consisting of at least two conducting layers, and two semiconductor layers forming a junction at their interface. Such modules are discussed in more details in the aforementioned U.S. application Ser. No. 12/034,883. The modules are separated and attached to electrically insulating, transparent substrates with embedded conducting grids 910 and further attached to a common substrate 920. Such a photovoltaic device may behave like a multi-junction photovoltaic device, if the bandgaps of respective light-absorbing semiconductor layers in the modules differ from each other, so that the upper module's semiconductor bandgap is larger than that of a lower module. Typically, the power conversion efficiency of a multi-junction photovoltaic device is higher than that of a single junction photovoltaic device. However, for this to occur, the light transmission between the modules 930, 940 and 950 has to be nearly lossless or at least preferably greater than 80-90%. Yet, for the same reason it is desirable to have a low contact resistance for each of the modules. Unlike conventional approaches, when the substrates 910 are constructed in accordance with the principles of the present invention, both requirements concerning optical transmission and resistance can be satisfied.

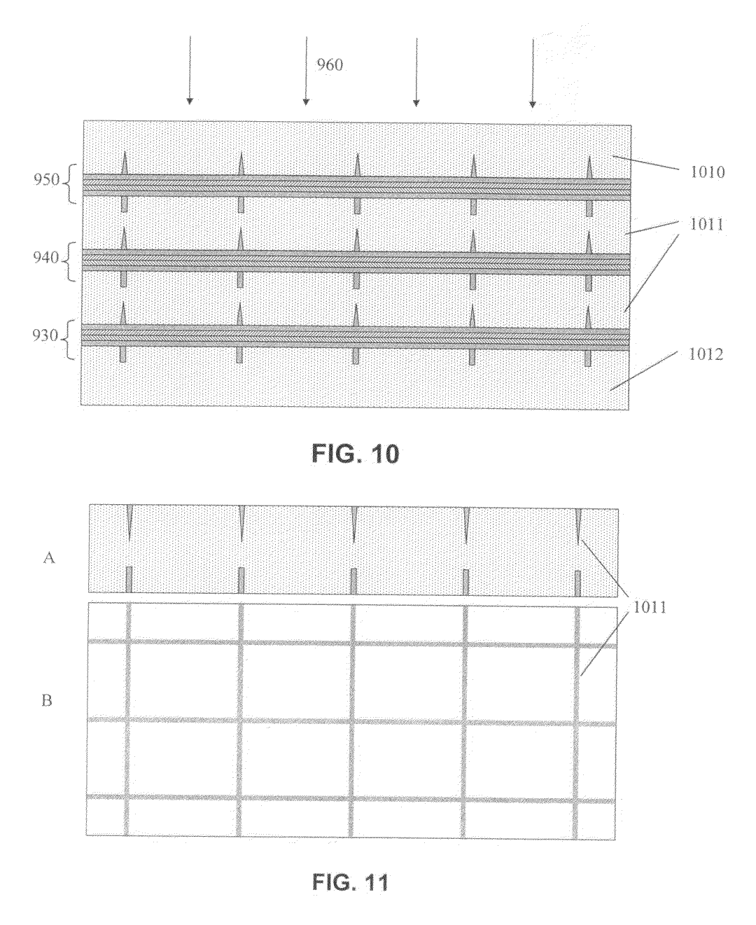

In another embodiment, the device in FIG. 9 is modified so that substrates 910 and 920 are replaced with a different set of substrates 1010, 1011, and 1012 of the type shown in FIG. 10. In this particular case substrate 1010 and 1012 are largely the same as the previously described substrate 910, in which there is a single embedded conducting grid disposed on one side of the substrate 910. Substrates 1011, however, have two conducting grids disposed on opposite sides of the substrate 1011. Substrate 1011 is also shown in a cross-sectional and top view, respectively, in FIG. 11. In this embodiment, the conducting grids disposed on each side of the substrate are used to lower the contact resistance of conducting layers in neighboring modules. By separating each module in the photovoltaic device with such a substrate the contact resistance of both conducting layers in each module can be reduced.

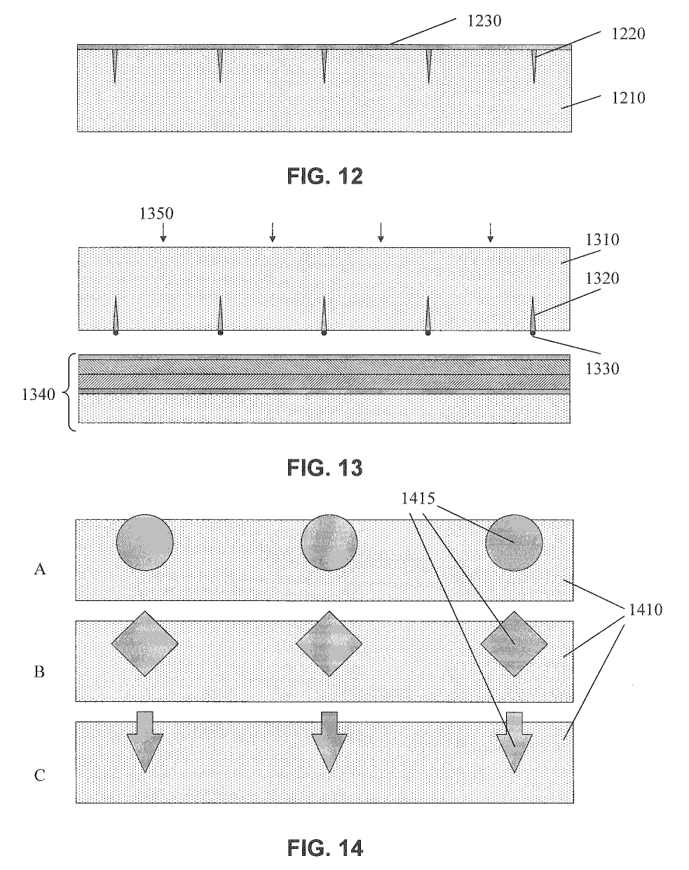

In another embodiment shown in FIG. 12 an insulating, transparent substrate 1210 having an embedded conducting grid 1220 is further coated with a thin layer of transparent conductor 1230, e.g. ITO. Such a substrate may be used as a base layer in a subsequent manufacturing of a thin-film photovoltaic device. That is, at least two semiconductor layers and an additional conducting layer may be sequentially deposited or grown directly on top of the conducting layer 1230.

In another embodiment shown in FIG. 13 an insulating, transparent substrate 1310 having an embedded conducting grid 1320 is hybridly attached to a photovoltaic module 1340. Solder or conductive epoxy bumps 1330 may be used for adhering the module 1340 to the substrate 1310 and for producing good electrical contacts between the conducting grid 1320 and the top conducting layer of the module 1340. FIG. 13 also shows the direction of incoming light 1350 that may be used for efficient power conversion by the photovoltaic module 1340.

In another embodiment shown in cross-section in FIG. 14 an insulating, transparent substrate 1410 has an embedded conducting grid 1415 with a variety of cross-sectional shapes. In this example a part of the grid located in each groove extends above the top surface of the substrate.

In another embodiment shown in FIG. 15 an insulating, transparent substrate 1510 has an embedded conducting grid 1515 with a variety of cross-sectional shapes, a part of which may extend above the top surface of the substrate. Furthermore, the exposed parts of the substrate may be coated with a thin layer of a transparent adhesive 1516.

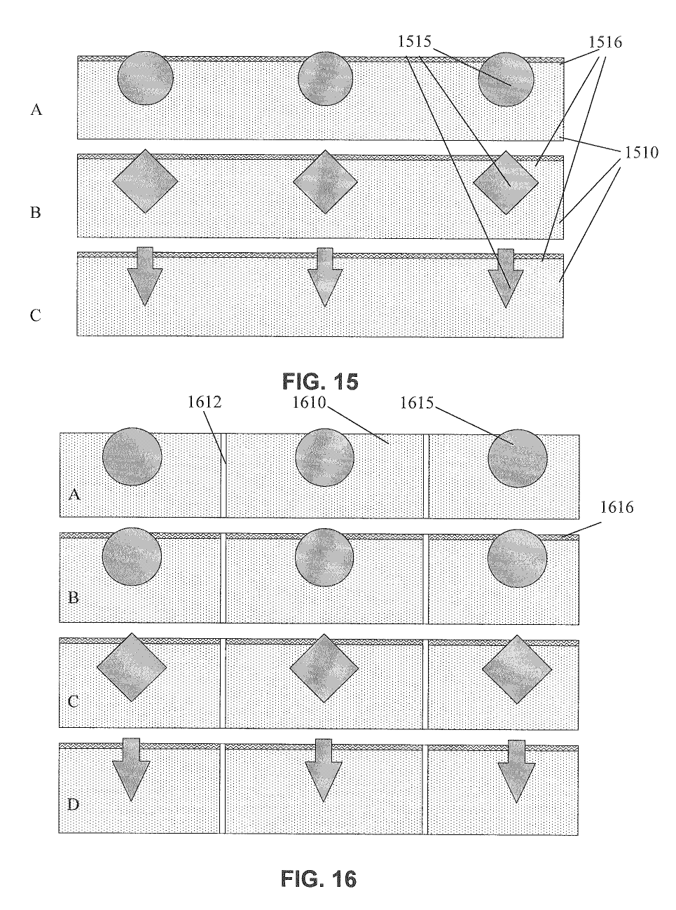

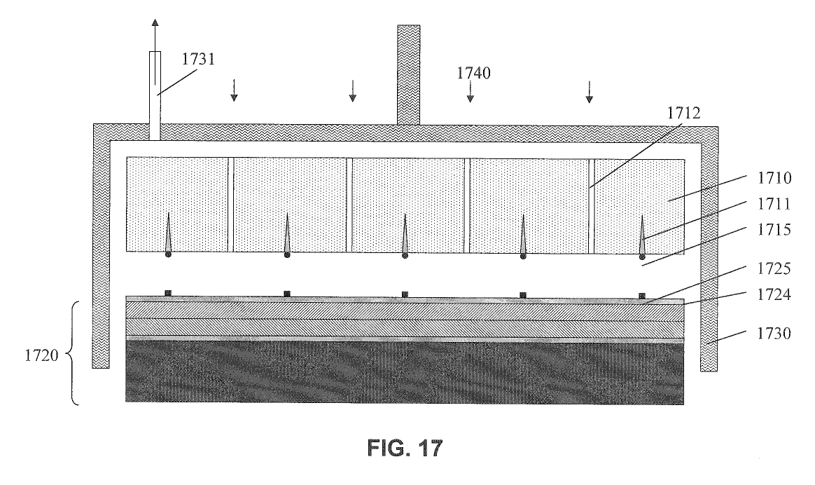

In another embodiment shown in FIG. 16 an insulating, transparent substrate 1610 has an embedded conducting grid 1615 with a variety of cross-sectional shapes, a part of which may extend above the top surface of the substrate. Furthermore, the exposed parts of the substrate may be coated with a thin layer of a transparent adhesive 1616. In this embodiment the substrate is perforated so that there are multiple through holes 1612 allowing air passage from one side of the substrate to the other. In some embodiments these holes may be cylindrical in shape, disposed evenly between the grid wires and have a diameter of about 0.05-0.5 mm. The through holes may serve to facilitate the attachment of the substrate to the photovoltaic module, as discussed in more detail below in connection with FIG. 17.

In another embodiment shown in FIG. 17, an apparatus is provided to implement a method for attaching in a hybrid manner a perforated, insulating, transparent substrate 1710 having an embedded conducting grid 1711 onto an exposed conducting layer 1724 of a photovoltaic module 1720. Solder bumps or conducting epoxy 1715 and 1725 may be disposed on the grid 1711 and the module 1720, respectively. The substrate 1710 may then be attached to the module 1720 by using a laminator 1730 to apply pressure, as indicated by reference numeral 1740. The laminator 1730 may also use local heating to raise the temperature of the substrate-module assembly to either reflow the solder bumps or cure the epoxy, thereby bonding the substrate 1710 to the module 1720. This attachment process may be assisted with a vacuum pump 1731, which removes air from the laminator cavity. Since the substrate is perforated with through holes 1712, air can escape from underneath the substrate during the attachment process, thus leading to a very close contact and strong bond between the corresponding surfaces.

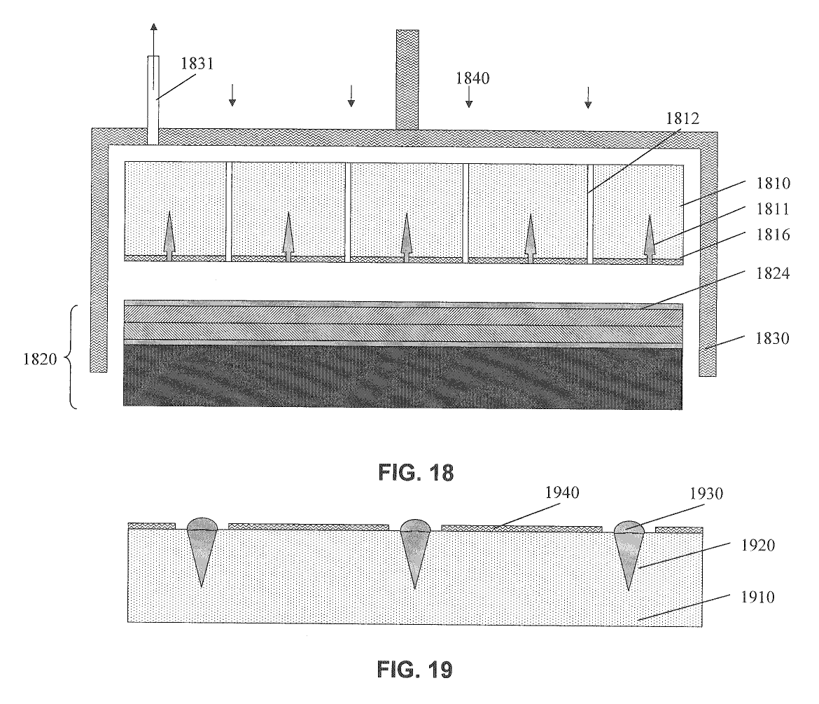

In another embodiment shown in FIG. 18, an apparatus is provided to implement a method for attaching in a hybrid manner a perforated, insulating, transparent substrate 1810 having an embedded conducting grid 1811 onto an exposed conducting layer 1824 of a photovoltaic module 1820. In this embodiment an additional transparent adhesive layer 1816 may be disposed on the substrate 1810. The substrate 1810 may then be attached to the module 1820 using a laminator 1830 to apply pressure, as indicated by reference numeral 1840. The laminator 1830 may also use local heating to raise the temperature of the assembly and activate the adhesive layer, thereby bonding the substrate to the module. This attachment process may be assisted with a vacuum pump 1831, which removes air from the laminator cavity. The through holes 1812 in the substrate 1810 allow air to escape from underneath the substrate 1810 during the attachment process, thus leading to a very close contact and strong bond between the corresponding surfaces.

In another embodiment shown in FIG. 19 a method is provided for manufacturing a transparent substrate with an embedded conducting grid. A flexible clear polymer substrate 1910 is shown in cross-section, which may be used as a starting material. The thickness range for this substrate may be between 20 microns and 1 mm. A pattern of grooves 1920 may be produced in the top of the substrate 1910 by either photolithographic etching or micro-stamping. The shape of the grooves in cross-section is triangular and elongated along the axis perpendicular to the substrate surface with an apex angle of less than 60°. The grooves 1920 may then be filled with a nanoparticle silver ink 1930, for example using the ink-jet printing, and cured, so that a part of the silver ink, which defines the conducting grid, is exposed and protrudes from the top surface of the substrate 1910. Furthermore, a thin layer (10-50 microns) of adhesive 1940, such as ethylene-vinylacetate (EVA), may be deposited on the substrate 1910 between the individual grid wires, which may be subsequently used to attach the substrate to a photovoltaic module.

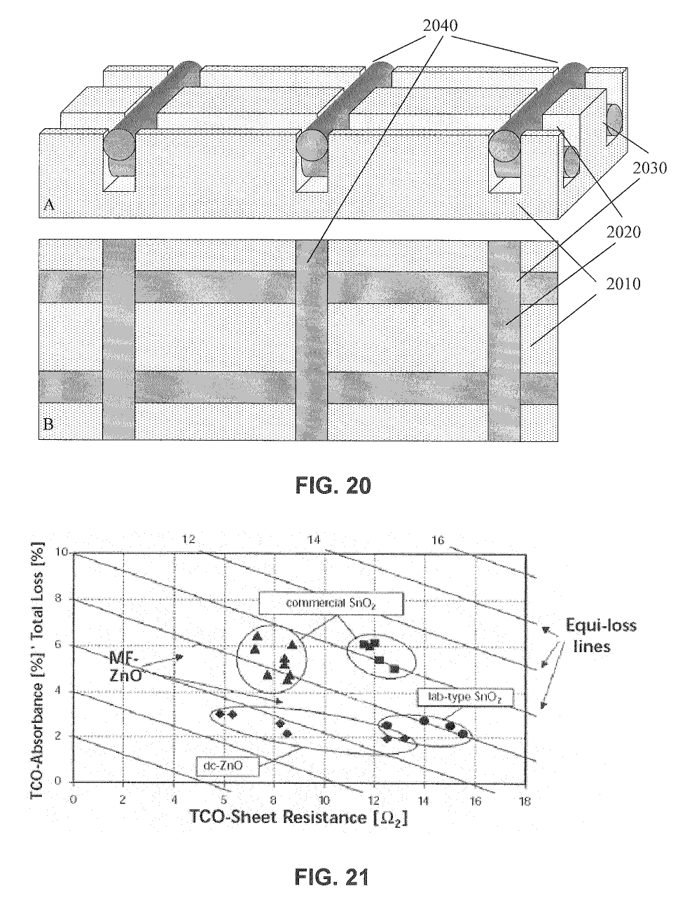

In yet another embodiment shown in a cross-sectional and top view in FIGS. 20a and 20b, respectively, an alternative method is employed for manufacturing a transparent substrate with an embedded conducting grid. In this case a clear glass substrate 2010 with a thickness in the range between 50 microns and 2000 mm may be used. A pattern of rectangular grooves 2020 may then be produced in the substrate 2010, using for example, either glass molding or photolithographic dry etching techniques. Subsequently, a first set of cylindrically shaped metal wires 2030 may be placed in the grooves, followed by a second set of metal wires 2040 that are oriented in the orthogonal direction with respect to the first set of metal wires 2030. The metal material in the wires could be gold or copper, and the wire diameter could be in the range of 25-100 microns, for instance. The width of the grooves 2020 may be chosen to be about equal to the diameter of the wires and the depth of the grooves 2020 may be chosen so that the top set of wires 2040 slightly protrude above the surface of the substrate 2010.

In yet another embodiment, the cross-sectional shape of the grooves 2020 shown in FIG. 20 may be modified so that they are similar in shape to the grooves shown in FIG. 4E so that most of the light may be transmitted through the substrate unimpeded. Furthermore, the apex angle may be chosen so that the resulting conducting grid is nonblocking.

In yet another embodiment, an adhesive is added into the grooves 2020 shown in FIG. 20 in order to secure the wires within the grooves and thus attach them to the substrate 2010.

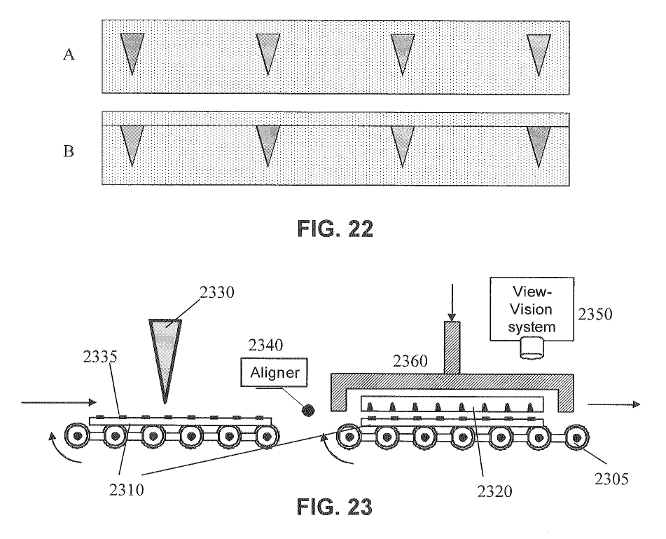

In yet another embodiment shown in FIGS. 22a and 22b the transparent substrates A and B, which have nonblocking reflecting grids, may be used to improve optical transmission through an electro-optical device by providing a pattern-matching metal grid on its top surface. When one of such substrates is attached to the top surface of the electro-optic device, its nonblocking reflecting grid will reflect and redirect light rays away from the metal grid, thereby reducing optical losses. Nonblocking reflecting grids may be produced from any reflecting material, including conducting materials and not excluding insulating and semiconducting materials. Furthermore, substrate B in FIG. 22b may be a laminate film composed of at least two layers.

FIG. 23 shows another embodiment of an apparatus that implements a method for attaching a composite substrate to an electro-optic device. A pick and place arrangement or a roller system 2305 may be used to handle electro-optic devices 2310 in this example. A soldering tool 2330 may be used to deposit a pattern of either solder or conducting epoxy bumps 2335 onto the electro-optic devices 2310. An aligner system 2340, with the aid of a view-vision system 2350 may be used to align composite substrate 2320 with the electro-optic device 2310. A pressure member may then exert the necessary heat and force to melt the bumps 2335 and bond substrate 2320 to device 2310.

Variations of the apparatus and method described above are possible without departing from the scope of the invention.

1. A composite substrate, comprising:
an optically transparent and electrically insulating base substrate;
a plurality of grooves disposed in said base substrate; and
an electrically conducting material filling said grooves.

2. The substrate of claim 1 wherein said plurality of grooves defines a pattern of grooves and the conducting material in each of the grooves collectively defines a conducting grid, said conducting grid being an optically nonblocking grid.

3. The substrate of claim 1 wherein said each of said grooves has a cross-section shape that extends in a direction perpendicular to a surface of said base substrate.

4. The substrate of claim 1 wherein at least one of said grooves has a triangular cross-section.

5. The substrate of claim 1 wherein at least one of said grooves has a cross-section with at least one re-entrant angle.

6. The substrate of claim 1 wherein said electrically conducting material is exposed at a surface of the base substrate so that it is accessible from the surface to thereby serve as electrical contacts.

7. The substrate of claim 6 wherein said electrically conducting material protrudes above the surface of said base substrate.

8. The substrate of claim 1 further comprising a layer of transparent adhesive layer disposed on at least one side of said base substrate.

9. The substrate of claim 1 further comprising a plurality of holes extending between top and bottom surfaces of said base substrate.

10. The substrate of claim 1 wherein said plurality of grooves defines a pattern of grooves, said pattern being a rectangular pattern.

11. The substrate of claim 1 where said electrically conducting material is a metal material.

12. The substrate of claim 1 where said electrically conducting material is a conducting ink.

13. The substrate of claim 1 where said electrically conducting material is a conducting polymer.

14. The substrate of claim 1 further comprising a transparent conducting layer disposed on top of the electrically conducting material to establish electrical contact therewith.

15. The substrate of claim 1 wherein said base substrate is made from glass.

16. The substrate of claim 1 wherein said base substrate is made from plastic.

17. The substrate of claim 1 wherein said plurality of grooves includes a first plurality of grooves disposed in a first surface of the base substrate and a second plurality of grooves disposed in a second surface of the base substrate.

18. An electro-optic device comprising:
at least one electro-optic module that includes first and second conductive layers and at least first and second semiconductor layers disposed between the conductive layers;
at least one optically transparent, electrically insulating base substrate disposed on said module, said base substrate having a plurality of grooves disposed therein and an electrically conducting material filling said grooves, whereby electrical contact is established between said conducting material and at least one of the conducting layers of said module.

19. The device of claim 18 wherein said semiconductor layers establish a photovoltaic junction at an interface therebetween.

20. The device of claim 18 wherein said modules comprise at least two electro-optic modules.

21. The device of claim 18 wherein said plurality of grooves defines a pattern of grooves and the conducting material in each of the grooves collectively defines a conducting grid, said conducting grid being an optically nonblocking grid.
